(19) United States
(12) Patent Application Publication
(10) Pub. No.: US 2023/0180468 A1
(43) Pub. Date: Jun. 8, 2023

(54) SEMICONDUCTOR MEMORY DEVICE

(71) Applicant: Samsung Electronics Co., Ltd., Suwon-si (KR)

(72) Inventors: Kiseok Lee, Hwaseong-si (KR); Moonyoung Jeong, Suwon-si (KR); Jong-Ho Moon, Seoul (KR); Han-Sik Yoo, Seongnam-si (KR); Keunnam Kim, Yongin-si (KR); Hyungeun Choi, Suwon-si (KR)

(21) Appl. No.: 18/052,689

(22) Filed: Nov. 4, 2022

(30) Foreign Application Priority Data
Dec. 7, 2021 (KR) 10-2021-0174208

(51) Int. Cl. H01L 27/108; H01L 25/065; H01L 25/18; H01L 23/00; H01L 25/00

(52) U.S. Cl. CPC H01L 27/10897; H01L 24/06; H01L 24/08; H01L 24/80; H01L 25/18; H01L 25/50; H01L 25/0657; H01L 27/10805; H01L 27/10894; H01L 2224/06515; H01L 2224/08145; H01L 2224/80006; H01L 2224/80895; H01L 2224/80896; H01L 2924/1431; H01L 2924/1436

(57) ABSTRACT

A semiconductor memory device may include a cell array structure including first bonding pads, which are electrically connected to memory cells, and a peripheral circuit structure including second bonding pads, which are electrically connected to peripheral circuits and are bonded to the first bonding pads. The cell array structure may include a stack including horizontal conductive patterns stacked in a vertical direction, a vertical structure including vertical conductive patterns , which are provided to cross the stack in the vertical direction, and a power capacitor provided in a planarization insulating layer covering a portion of the stack.

### CROSS-REFERENCE TO RELATED APPLICATIONS

This U.S. non-provisional patent application claims priority under 35 U.S.C. §119 to Korean Patent Application No. 10-2021-0174208, filed on Dec. 7, 2021, in the Korean Intellectual Property Office, the entire contents of which are hereby incorporated by reference.

### FIELD

The present disclosure relates to a semiconductor memory device, and in particular, to a three-dimensional semiconductor memory device with improved reliability and an increased integration density.

### BACKGROUND

Higher integration of semiconductor devices may be required to satisfy consumer demand for superior performance and inexpensive prices. In the case of semiconductor devices, since integration may be a factor in determining product prices, increased integration may be of particular value. In the case of two-dimensional or planar semiconductor devices, since integration may be mainly determined by the area occupied by a unit memory cell, integration may be greatly influenced by the level of a fine pattern forming technology. However, expensive process equipment that may be needed to increase pattern fineness may set a practical limitation on increasing integration for two-dimensional or planar semiconductor devices. Thus, three-dimensional semiconductor memory devices including three-dimensionally arranged memory cells have been proposed.

### SUMMARY

Embodiments of the inventive concepts provide a semiconductor memory device with improved reliability and an increased integration density.

According to an embodiment of the inventive concept, a semiconductor memory device may include a cell array structure comprising first bonding pads, which are electrically connected to memory cells, and a peripheral circuit structure comprising second bonding pads, which are electrically connected to peripheral circuits and are bonded to the first bonding pads. The cell array structure may include a stack comprising horizontal conductive patterns stacked in a vertical direction, a vertical structure comprising vertical conductive patterns , which intersect the stack in the vertical direction, and a power capacitor in a planarization insulating layer on a portion of the stack.

According to an embodiment of the inventive concept, a semiconductor memory device may include a cell array structure comprising first bonding pads electrically connected to memory cells, and a peripheral circuit structure comprising second bonding pads, which are electrically connected to peripheral circuits and are bonded to the first bonding pads. The cell array structure may include a lower insulating layer having a first surface and a second surface, which are opposite to each other, a stack comprising horizontal conductive patterns , which are stacked on the first surface of the lower insulating layer, a vertical structure comprising vertical conductive patterns penetrating the stack, a power capacitor in a planarization insulating layer on the stack, an input/output plug penetrating the planarization insulating layer, and an input/output pad on the second surface of the lower insulating layer and electrically connected to the input/output plug. The power capacitor may be between the first bonding pads and the input/output pads, when viewed in a vertical section.

According to an embodiment of the inventive concept, a semiconductor memory device may include a cell array structure comprising first bonding pads electrically connected to memory cells and including a cell array region, and a first peripheral region that is adjacent the cell array region; and a peripheral circuit structure comprising second bonding pads electrically connected to peripheral circuits and are bonded to the first bonding pads. The peripheral circuit structure comprises a first core region that overlaps with the bit line connection region in a vertical direction, a second core region that overlaps with the word line connection region in a vertical direction, and a second peripheral region that overlaps with the first peripheral region in a vertical direction. The cell array structure may include a lower insulating layer having a first surface and a second surface, which are opposite to each other, a stack comprising word lines in the cell array region and stacked on the first surface of the lower insulating layer in a vertical direction, a vertical structure comprising bit lines in the cell array region and penetrating the stack, a planarization insulating layer in the cell array region and the first peripheral region and on the stack, and a power capacitor in the first peripheral region and in the planarization insulating layer. The power capacitor comprises a first metal pattern in an opening in the planarization insulating layer, a second metal pattern on the first metal pattern, and a dielectric material pattern between the first metal pattern and the second metal pattern. An input/output plug is provided in the first peripheral region and penetrates the planarization insulating layer, and an input/output pad is in the first peripheral region and on the second surface of the lower insulating layer and is electrically connected to the input/output plug.

### BRIEF DESCRIPTION OF THE DRAWINGS

FIG. 1 is a block diagram illustrating a semiconductor memory device according to an embodiment of the inventive concept.

FIG. 2 is a schematic perspective view illustrating a semiconductor memory device according to an embodiment of the inventive concept.

FIG. 3 is a sectional view illustrating a semiconductor memory device according to an embodiment of the inventive concept.

FIG. 4 is a perspective view illustrating a portion of a semiconductor memory device according to an embodiment of the inventive concept.

FIG. 5 is a plan view illustrating a cell array structure of a semiconductor memory device according to an embodiment of the inventive concept.

FIG. 6 is a sectional view, which is taken along lines I-I′ and II-II′ of FIG. 5 to illustrate a cell array structure of a semiconductor memory device according to an embodiment of the inventive concept.

FIG. 7 is an enlarged sectional view illustrating a portion ‘P’ of FIG. 6.

FIG. 8 is a perspective view illustrating a portion of a cell array structure of a semiconductor memory device according to an embodiment of the inventive concept.

FIGS. 9, 10, 11, 12, 13, 14, and 15 are sectional views illustrating a method of fabricating a semiconductor memory device according to an embodiment of the inventive concept.

### DETAILED DESCRIPTION

Example embodiments of the inventive concepts will now be described more fully with reference to the accompanying drawings, in which example embodiments are shown.

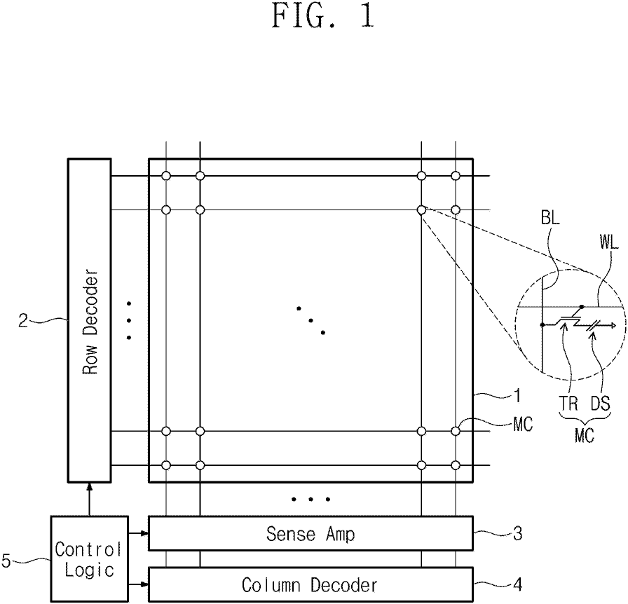

FIG. 1 is a block diagram illustrating a semiconductor memory device according to an embodiment of the inventive concept.

Referring to FIG. 1, a semiconductor memory device may include a memory cell array 1, a row decoder 2, a sensing amplifier 3, a column decoder 4, and a control logic 5.

The memory cell array 1 may include a plurality of memory cells MC, which are three-dimensionally arranged. Each of the memory cells MC may be provided between and electrically connected to a word line WL and a bit line BL, which are disposed to cross each other.

Each of the memory cells MC may include a selection element TR and a data storage element DS, which are electrically connected to each other in series. The selection element TR may be a field effect transistor (FET), and the data storage element DS may be realized with a capacitor, a variable resistor, or the like. As an example, the selection element TR may include a transistor whose gate electrode is electrically connected to the word line WL and whose drain/source terminals are electrically connected to the bit line BL and the data storage element DS, respectively.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sensing amplifier 3 may be configured to sense, amplify, and output a difference in voltage between one of the bit lines BL, which is selected based on address information decoded by the column decoder 4, and a reference bit line.

The column decoder 4 may provide a data transmission path between the sensing amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

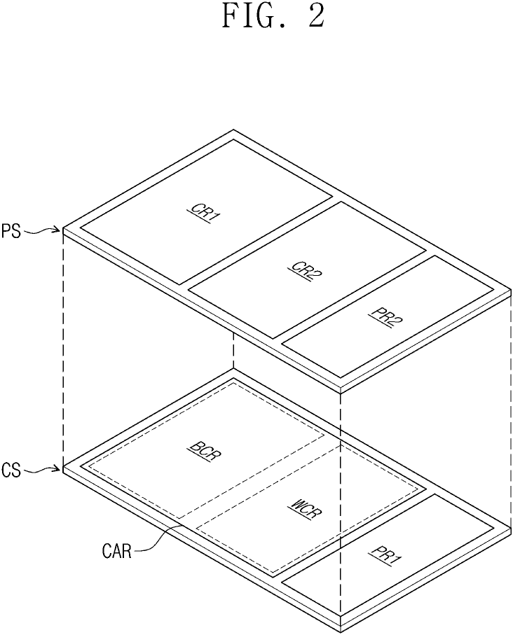

FIG. 2 is a schematic perspective view illustrating a semiconductor memory device according to an embodiment of the inventive concept.

Referring to FIG. 2, a semiconductor memory device may include a cell array structure CS and a peripheral circuit structure PS.

The cell array structure CS may include a memory cell array region CAR and a first peripheral region PR1. A memory cell array region CAR may include a bit line connection region BCR and a word line connection region WCR. The terms first, second, etc. may be used herein merely to distinguish one element from another.

The memory cell array 1 (e.g., see FIG. 1) may be provided in the memory cell array region CAR. As described with reference to FIG. 1, the memory cell array may include word and bit lines, which are disposed to cross each other, and memory cells, which are provided therebetween. The word lines may extend in a horizontal direction (and may thus be referred to herein as horizontal conductive patterns), and the bit lines may extend in a vertical direction (and may thus be referred to herein as vertical conductive patterns). The memory cells MC of the memory cell array may be three-dimensionally arranged. The bit lines may be provided in the bit line connection region BCR, and the word lines may be provided in the bit line connection region BCR and the word line connection region WCR.

The peripheral circuit structure PS may include a first core region CR1, a second core region CR2, and a second peripheral region PR2. The first and second core regions CR1 and CR2 may be vertically overlapped with the memory cell array region CAR. The second peripheral region PR2 may be vertically overlapped (e.g. overlapping in the vertical direction D3 described herein) with the first peripheral region PR1.

A plurality of sense amplifiers may be provided in the first core region CR1, and a plurality of sub-word line drivers may be provided in the second core region CR2.

A control signal generating circuit for controlling the sub-word line driver and a control signal generating circuit for controlling the sense amplifier may be provided in the first and second peripheral regions PR1 and PR2. In addition, voltage generators providing operation voltages to the sense amplifier and the sub-word line driver may be disposed in the first and second peripheral regions PR1 and PR2.

In an embodiment, a power capacitor (or a decoupling capacitor), which is used to filter noise between operating or operation powers to be input to the semiconductor memory device, may be provided in the first peripheral region PR1.

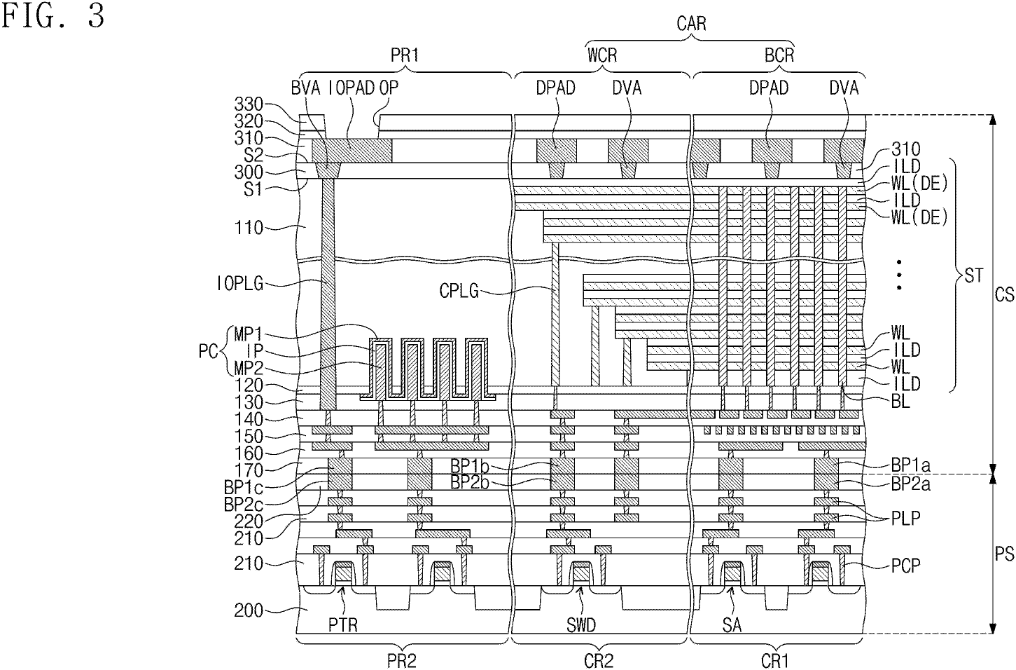

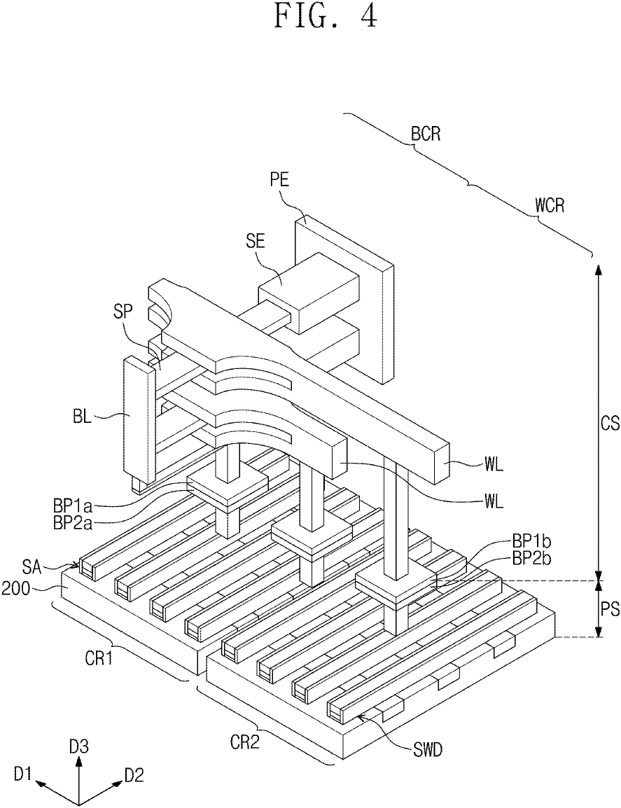

FIG. 3 is a sectional view illustrating a semiconductor memory device according to an embodiment of the inventive concept. FIG. 4 is a perspective view illustrating a portion of a semiconductor memory device according to an embodiment of the inventive concept.

Referring to FIGS. 3 and 4, a semiconductor memory device may have a chip-to-chip (C2C) structure. For the C2C structure, an upper chip including the cell array structure CS may be fabricated on a first wafer, a lower chip including the peripheral circuit structure PS may be fabricated on a second wafer different from the first wafer, and the upper chip and the lower chip may be connected to each other through a bonding method. The bonding method may mean or refer to a way of electrically connecting a bonding metal formed in the uppermost metal layer of the upper chip to a bonding metal formed in the uppermost metal layer of the lower chip. For example, in the case where the bonding metal is formed of copper (Cu), the bonding method may be a Cu-to-Cu bonding method, but in an embodiment, aluminum (Al) or tungsten (W) may be used as the bonding metal.

In detail, the cell array structure CS may include the cell array region CAR and the first peripheral region PR1, and the cell array region CAR may include the bit line connection region BCR and the word line connection region WCR.

The cell array structure CS may include horizontal patterns (e.g., word lines), which are provided in the cell array region CAR and are sequentially stacked on a lower insulating layer 300, vertical patterns (e.g., bit lines), which are provided to vertically cross the horizontal patterns, and memory elements, which are interposed between the horizontal and vertical patterns.

In more detail, the cell array structure CS may include the lower insulating layer 300, which has first and second surfaces S1 and S2 that are opposite to each other, the word lines WL, the bit lines BL, a power capacitor PC, an input/output contact plug IOPLG, and first bonding pads BP1a, BP1b, and BP1c.

The lower insulating layer 300 may have the first surface S1 and the second surface S2, which are opposite to each other. A stack ST, in which interlayer insulating patterns ILD and the word lines WL are alternately stacked, may be disposed on the first surface S1 of the lower insulating layer 300.

The word lines WL may be parallel to the first surface S1 of the lower insulating layer 300, and the bit lines BL may extend in a third direction D3 (e.g., a vertical direction) perpendicular to the first surface S1 of the lower insulating layer 300. Meanwhile, in an embodiment, the word lines WL are described to be parallel to the first surface S1 of the lower insulating layer 300, but the inventive concept is not limited to this example. For example, the bit lines BL may be parallel to the first surface S1 of the lower insulating layer 300, and the word lines WL may extend in the third direction D3.

The word lines WL may extend from the bit line connection region BCR to the word line connection regions WCR, and the bit lines BL may be provided on the bit line connection region BCR. The word lines WL may include pad portions, which are provided on the word line connection region WCR and are connected to cell contact plugs CPLG. The word lines WL may be stacked on the word line connection region WCR to have a staircase structure. The pad portions of the word line WL may be located at different positions in horizontal and vertical directions. In an embodiment, some of the word lines WL, which are adjacent to the lower insulating layer 300, may be used as dummy word lines DE.

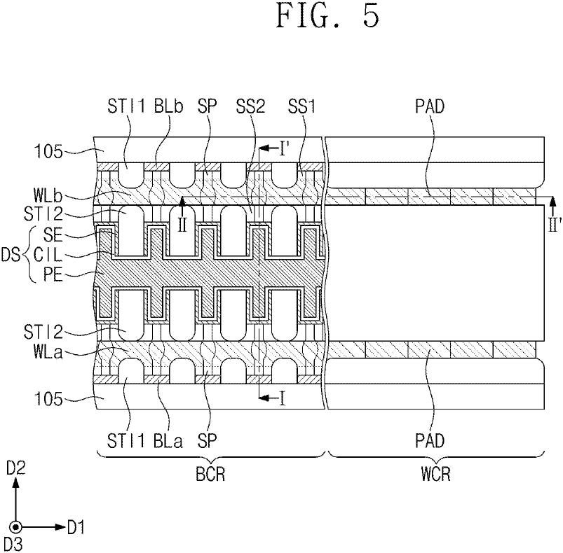

In an embodiment, each of the word lines WL may be provided to cross opposite surfaces of a semiconductor pattern SP or to have a double gate structure, as shown in FIG. 4. The semiconductor pattern SP may have a first side surface, which is connected to the bit line BL, and a second side surface, which is connected to the word line WL. The cell array structure CS will be described in more detail with reference to FIGS. 5 to 8.

A planarization insulating layer 110 may be disposed in the word line connection region WCR and the first peripheral region PR1 and on the first surface S1 of the lower insulating layer 300. The planarization insulating layer 110 may cover a staircase structure of the stack ST. That is, the planarization insulating layer 110 may cover the pad portions of the word lines WL.

The power capacitor PC may be provided in the first peripheral region PR1 and in the planarization insulating layer 110. The power capacitor PC may constitute or otherwise provide a voltage generator which receives a power voltage input through an input/output pad IOPAD and outputs operation voltages for operating the memory cell array. In addition, the power capacitor PC may be configured to perform a filtering operation on noise between operating or operation powers, which are input through the input/output pad IOPAD.

In an embodiment, the power capacitor PC may be located between the input/output pads IOPAD and the first bonding pads BP1a, BP1b, and BP1c, when viewed in a vertical section (i.e., a cross-section taken along a vertical direction). The power capacitor PC may include a first metal pattern MP1, which is provided to conformally cover openings formed in the planarization insulating layer 110, second metal patterns MP2, which are respectively provided in the openings covered with the first metal pattern MP1, and a dielectric material pattern IP, which is provided between the first metal pattern MP1 and the second metal patterns MP2.

The first metal pattern MP1 of the power capacitor PC may be vertically spaced apart from the lower insulating layer 300. When measured in the third direction D3, a length (also referred to as a height along the vertical direction) of the first metal pattern MP1 may be smaller than a thickness of the stack ST.

The first metal pattern MP1 may be provided to have a uniform thickness, to cover side and bottom surfaces of the opening, and to have a cylindrical shape or a concave shape. In another embodiment, the first metal pattern MP1 may have a pillar shape extending in the third direction D3. In other embodiments, a portion of the first metal pattern MP1 may have a pillar shape, and another portion of the first metal pattern MP1 may have a concave shape; that is, the first metal pattern MP1 may have a hybrid structure.

The first and second metal patterns MP1 and MP2 of the power capacitor PC may be formed of or include at least one of doped semiconductor materials (e.g., doped silicon and doped germanium), conductive metal nitride materials (e.g., titanium nitride and tantalum nitride), metallic materials (e.g., tungsten, titanium, and tantalum), or metal-semiconductor compounds (e.g., tungsten silicide, cobalt silicide, and titanium silicide).

The power capacitor PC may be electrically connected to some of the first bonding pads BP1a, BP1b, and BP1c through contact plugs and conductive lines. In an embodiment, on a first interlayer insulating layer 120 covering the bit lines BL, the first metal pattern MP1 may be electrically connected to a contact plug (not shown).

The input/output contact plug IOPLG may be provided in the second peripheral region PR2 to penetrate the planarization insulating layer 110 and first and second interlayer insulating layers 120 and 130. The input/output contact plug IOPLG may be electrically connected to some of the first bonding pads BP1a, BP1b, and BP1c through contact plugs and conductive lines.

The first bonding pads BP1a, BP1b, and BP1c of the cell array structure CS may include first upper bonding pads BP1a provided in the bit line connection region BCR, second upper bonding pads BP1b provided in the word line connection regions WCR, and third upper bonding pads BP1c provided in the second peripheral region PR2.

The first upper bonding pads BP1a may be electrically connected to the bit lines BL through conductive lines and contact plugs, and the second upper bonding pads BP1b may be electrically connected to the cell contact plugs CPLG and the word lines WL through conductive lines and contact plugs. The third upper bonding pads BP1c may be electrically connected to the power capacitor PC and the input/output contact plug IOPLG through conductive lines and contact plugs.

In an embodiment, the input/output pads IOPAD and dummy pads DPAD may be disposed on the second surface S2 of the lower insulating layer 300.

In the second peripheral region PR2, the input/output pads IOPAD may be electrically connected to the input/output contact plug IOPLG through input/output vias BVA. The dummy pads DPAD may be provided on the bit line connection region BCR and the word line connection region WCR. The dummy pads DPAD may be electrically connected to dummy vias DVA. The dummy vias DVA may be surrounded by an insulating material and may be in an electrically-floated state, and the dummy pads DPAD and the dummy vias DVA may extend toward the cell array structure and may be used as a pathway for supplying hydrogen during the process of fabricating the semiconductor memory device. The input/output pads IOPAD and the dummy pads DPAD may be formed of or include the same metallic material (e.g., aluminum).

A protection layer 310 may be disposed on the second surface S2 of the lower insulating layer 300 to cover the input/output pads IOPAD and the dummy pads DPAD. The protection layer 310 may be a hydrogen-containing oxide layer. A hydrogen concentration in the protection layer 310 may be higher than a hydrogen concentration in the lower insulating layer 300. The protection layer 310 may be a high density plasma (HDP) oxide layer or a tetraethylortho silicate (TEOS) layer.

A capping insulating layer 320 and a passivation layer 330 may be sequentially formed on the protection layer 310. The capping insulating layer 320 and the passivation layer 330 may have a pad opening OP exposing a portion of the input/output pad IOPAD.

The capping insulating layer 320 may include, for example, a silicon nitride layer or a silicon oxynitride layer. The passivation layer 330 may be formed of or include at least one of polyimide-based materials (e.g., photo sensitive polyimide (PSPI)).

The peripheral circuit structure PS may include a semiconductor substrate 200, core and peripheral circuits SA, SWD, and PTR, which are provided on the semiconductor substrate 200, and second bonding pads BP2a, BP2b, and BP2c.

The peripheral circuit structure PS may include the first core region CR1, the second core region CR2, and the second peripheral region PR2.

A plurality of sense amplifiers SA may be provided on the first core region CR1 of the semiconductor substrate 200. A plurality of sub-word line drivers SWD may be provided on the second core region CR2 of the semiconductor substrate 200. Control circuits PTR may be provided on the second peripheral region PR2 of the semiconductor substrate 200.

Peripheral interlayer insulating layers 210 and 220 may be provided on a top surface of the semiconductor substrate 200. The peripheral interlayer insulating layers 210 and 220 may be provided on the semiconductor substrate 200 to cover the peripheral circuits SA, SWD, and PTR, peripheral contact plugs PCP, and peripheral circuit or peripheral conductive lines PLP. The peripheral contact plugs PCP and the peripheral conductive lines PLP may be electrically connected to the peripheral circuits SA, SWD, and PTR. Each of the peripheral interlayer insulating layers 210 and 220 may include a silicon oxide layer, a silicon nitride layer, a silicon oxynitride layer, and/or a low-k dielectric layer.

The second bonding pads BP2a, BP2b, and BP2c of the peripheral circuit structure PS may include first lower bonding pads BP2a provided in the first core region CR1, second lower bonding pads BP2b provided in the second core region CR2, and third lower bonding pads BP2c provided in the second peripheral region PR2.

The first lower bonding pads BP2a may be electrically connected to the sense amplifiers SA through peripheral conductive lines PLP and the peripheral contact plugs PCP. The second lower bonding pads BP2b may be electrically connected to the sub-word line drivers SWD through the peripheral conductive lines PLP and the peripheral contact plugs PCP. The third lower bonding pads BP2c may be electrically connected to the control circuits PTR through the peripheral conductive lines PLP and the peripheral contact plugs PCP.

In an embodiment, the first, second, and third lower bonding pads BP2a, BP2b, and BP2c may be directly connected to the first, second, and third upper bonding pads BP1a, BP1b, and BP1c, respectively. As used herein, when an element or layer is directly on or directly connected to another element or layer, no intervening elements or layers are present. The first, second, and third lower and upper bonding pads BP1a, BP1b, BP1c, BP2a, BP2b, and BP2c may be formed of or include the same metallic material and may have substantially the same size or area. The first, second, and third lower and upper bonding pads BP1a, BP1b, BP1c, BP2a, BP2b, and BP2c may be formed of or include at least one of, for example, copper (Cu), aluminum (Al), nickel (Ni), cobalt (Co), tungsten (W), titanium (Ti), tin (Sn), or alloys thereof.

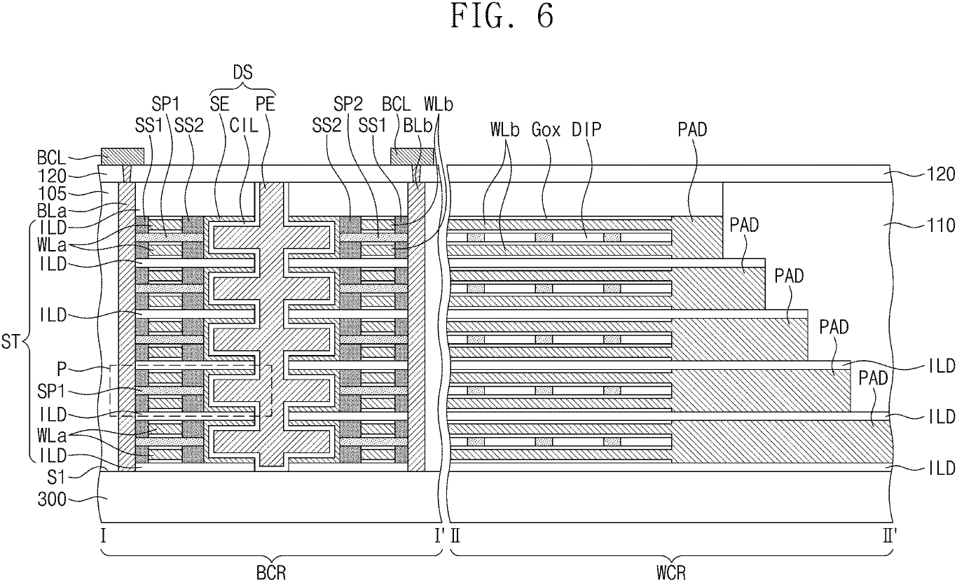

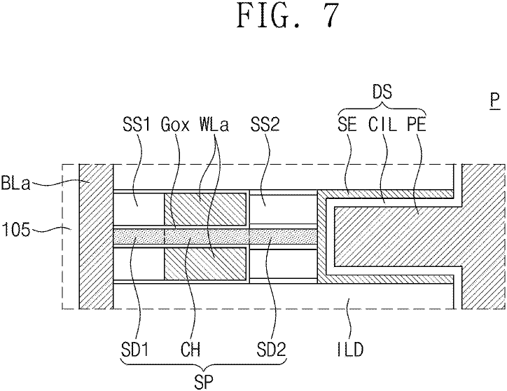

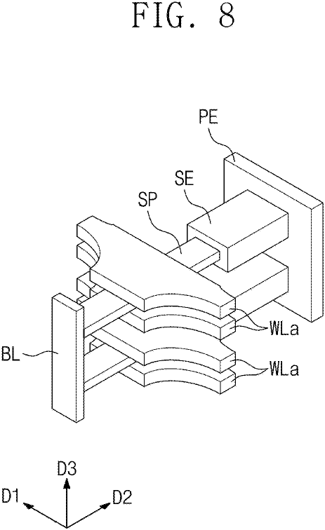

FIG. 5 is a plan view illustrating a cell array structure of a semiconductor memory device according to an embodiment of the inventive concept. FIG. 6 is a sectional view, which is taken along lines I-I′ and II-II′ of FIG. 5 to illustrate a cell array structure of a semiconductor memory device according to an embodiment of the inventive concept. FIG. 7 is an enlarged sectional view illustrating a portion ‘P’ of FIG. 6. FIG. 8 is a perspective view illustrating a portion of a cell array structure of a semiconductor memory device according to an embodiment of the inventive concept.

Referring to FIGS. 5 and 6, the stacks ST may be disposed on the first surface S1 of the lower insulating layer 300. The stacks ST may extend in a first direction D1 and may be spaced apart from each other in a second direction D2 crossing the first direction D1. Here, the first and second directions D1 and D2 may be parallel to the first or top surface S1 of the lower insulating layer 300.

Each of the stacks ST may include the word lines WLa and WLb, which are provided on the lower insulating layer 300 and are stacked in the third direction D3 (i.e., a vertical direction), which is perpendicular to the first and second directions D1 and D2, with the interlayer insulating patterns ILD interposed therebetween.

The word lines WLa and WLb may be formed of or include at least one of doped semiconductor materials (e.g., doped silicon and doped germanium), conductive metal nitride materials (e.g., titanium nitride and tantalum nitride), metallic materials (e.g., tungsten, titanium, and tantalum), or metal-semiconductor compounds (e.g., tungsten silicide, cobalt silicide, and titanium silicide).

In an embodiment, each of the word lines WLa and WLb may be provided to face top and bottom surfaces of the semiconductor pattern SP or to have a double gate structure, as shown in FIG. 8. In another embodiment, each of the word lines WLa and WLb may be provided to completely surround the semiconductor pattern SP or to have a gate-all-around structure.

In an embodiment, the word lines WLa and WLb may include the first and second word lines WLa and WLb, which face each other in the second direction D2. Each of the first and second word lines WLa and WLb may include a line portion, which extends in the first direction D1 parallel to the first surface S1 of the lower insulating layer 300, and gate electrode portions, which extend from the line portion in the second direction D2 to have a protruding shape, as shown in FIG. 8. Here, the line portion may be disposed between first and second insulating isolation patterns STI1 and STI2. In addition, when measured in the second direction D2, a width of the gate electrode portion may be larger than a width of the line portion. When viewed in a plan view, the first and second word lines WLa and WLb may be disposed to have a mirror symmetry about a plate electrode PE.

Each of the word lines WLa and WLb may have a pad portion PAD provided on the word line connection region WCR. The pad portions PAD of the word lines WLa and WLb may be stacked to form a staircase structure, and the planarization insulating layer 110 may be provided to cover the pad portions PAD. As a distance from the lower insulating layer 300 increases, a length of the word lines WLa and WLb in the first direction D1 may decrease.

The semiconductor patterns SP may be stacked in the third direction D3 and may be spaced apart from each other in the first and second directions D1 and D2. That is, the semiconductor patterns SP may be three-dimensionally arranged on the lower insulating layer 300. In the case where the word lines WL have the double gate structure, dummy insulating patterns DIP may be disposed between the semiconductor patterns SP, which are arranged in the first direction D1, and between a pair of sub-word lines.

The semiconductor patterns SP may be formed of or include at least one of silicon (Si), germanium (Ge), or silicon germanium (SiGe). As an example, the semiconductor patterns SP may be formed of or include single crystalline silicon. In an embodiment, the semiconductor patterns SP may have a band gap energy that is greater than that of silicon. For example, the semiconductor patterns SP may have a band gap energy of about 1.5 eV to 5.6 eV. When the semiconductor patterns SP have a band gap energy of about 2.0 eV to 4.0 eV, the semiconductor patterns SP may have optimal channel performance. As an example, the semiconductor patterns SP may be formed of or include at least one of oxide semiconductor materials (e.g., ZnₓSn_{y}O (ZTO), InₓZn_{y}O (IZO), ZnₓO, InₓGa_{y}Zn_{z}O (IGZO), InₓGa_{y}Si_{z}O (IGSO), InₓW_{y}O (IWO), InₓO, SnₓO, TiₓO, ZnₓON_{z}, MgₓZn_{y}O, ZrₓIn_{y}Zn_{z}O, HfₓIn_{y}Zn_{z}O, SnₓIn_{y}Zn_{z}O, AlₓSn_{y}In_{z}ZnₐO, SiₓIn_{y}Zn_{z}O, AlₓZn_{y}Sn_{z}O, GaₓZn_{y}Sn_{z}O, ZrₓZn_{y}Sn_{z}O, or combinations thereof).

Each of the semiconductor patterns SP may have a long axis parallel to the second direction D2 and may be a bar-shaped pattern, as shown in FIGS. 7 and 8. In detail, referring to FIG. 8, each of the semiconductor patterns SP may include first and second source-drain regions SD1 and SD2, which are spaced apart from each other, and a channel region CH between the first and second source-drain regions SD1 and SD2. The first and second source-drain regions SD1 and SD2 of each semiconductor pattern SP may be doped with impurities.

A gate insulating layer Gox may be interposed between the channel regions CH of the semiconductor patterns SP and the word lines WLa and WLb. The gate insulating layers Gox may be formed of or include at least one of high-k dielectric materials, silicon oxide, silicon nitride, or silicon oxynitride and may have a single- or multi-layered structure. In an embodiment, the high-k dielectric materials may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

First spacer insulating patterns SS1 may be respectively disposed between vertically adjacent ones of the interlayer insulating patterns ILD. The first spacer insulating patterns SS1 may be provided to surround the first source-drain region SD1 of the semiconductor pattern SP. A second spacer insulating pattern SS2 may be provided to surround the second source-drain region SD2 of the semiconductor pattern SP.

The first side surface of the semiconductor pattern SP may be in contact with the bit line BL, and the second side surface of the semiconductor pattern SP may be in contact with a storage electrode SE. Elements or layers that are described as “in contact” or “in contact with” other elements or layers may refer to physical contact.

Referring back to FIGS. 5 and 6, bit lines BLa and BLb may extend in the third direction D3, which is perpendicular to the first surface S1 of the lower insulating layer 300, to cross the word lines WLa and WLb. The bit lines BLa and BLb may have substantially the same length or height, when measured in the third direction D3. The bit lines BLa and BLb may be arranged to be spaced apart from each other in the first and second directions D1 and D2. Each of the bit lines BLa and BLb may be electrically connected to the first source-drain regions SD1 of the semiconductor patterns SP, which are stacked in the third direction D3. The bit lines BL may be electrically connected to bit line connection lines BCL, which are provided on the first interlayer insulating layer 120, through contact plugs.

The data storage element DS may be electrically connected to the second source-drain region SD2 of each semiconductor pattern SP. In an embodiment, the data storage element DS may be a capacitor, and the data storage element DS may include the storage electrode SE, the plate electrode PE, and a capacitor dielectric layer CIL therebetween.

The storage electrode SE may be electrically connected to the second source-drain region SD2 of each semiconductor pattern SP. Each of the storage electrodes SE may be provided at substantially the same level as a corresponding one of the semiconductor patterns SP. In other words, the storage electrodes SE may be stacked in the third direction D3 and may have a long axis parallel to the second direction D2. The storage electrodes SE may be respectively disposed between vertically adjacent ones of the interlayer insulating patterns ILD.

The capacitor dielectric layer CIL may be provided to conformally cover the storage electrodes SE. The plate electrode PE may be provided to fill inner spaces of the storage electrodes SE, which are covered with the capacitor dielectric layer CIL.

The first insulating isolation patterns STI1 may be respectively disposed between the bit lines BLa, which are adjacent to each other in the first direction D1. The first insulating isolation patterns STI1 may extend in the third direction D3.

The second insulating isolation patterns STI2 may be respectively disposed between the storage electrodes SE, which are adjacent to each other in the first direction D1. The second insulating isolation patterns STI2 may extend in the third direction D3.

Insulating gapfill patterns 105 may be provided on the lower insulating layer 300 and may extend in the first direction D1. The insulating gapfill patterns 105 may be provided to cover side surfaces of the bit lines BLa and BLb and side surfaces of the first insulating isolation patterns STI1. The insulating gapfill patterns 105 may be formed of or include at least one of silicon oxide, silicon oxynitride, or insulating materials, which are formed of using a spin-on-glass (SOG) technology.

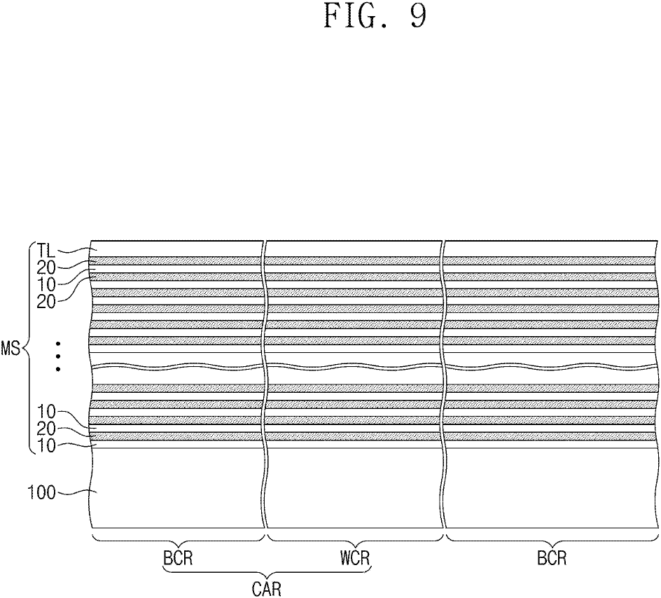

FIGS. 9 to 15 are sectional views illustrating a method of fabricating a semiconductor memory device according to an embodiment of the inventive concept.

Referring to FIG. 9, a mold structure MS may be formed on a first semiconductor substrate 100. The mold structure MS may include first semiconductor layers 10 and second semiconductor layers 20, which are alternately stacked on the first semiconductor substrate 100.

The first semiconductor layers 10 may be formed of or include at least one of, for example, silicon, germanium, silicon-germanium, or indium gallium zinc oxide (IGZO). In an embodiment, the first semiconductor layers 10 may be formed of or include the same semiconductor material as the lower insulating layer 300. For example, the first semiconductor layers 10 may be formed by an epitaxial growth method and may be a single crystalline silicon layer.

The second semiconductor layers 20 may be formed of or include at least one of, for example, silicon germanium, silicon oxide, silicon nitride, or silicon oxynitride. In an embodiment, the second semiconductor layers 20 may be formed by an epitaxial growth method and may be, for example, a silicon germanium layer. A thickness of the second semiconductor layers 20 may be substantially equal to or smaller than a thickness of the first semiconductor layers 10.

An upper insulating layer TL may be formed on the mold structure MS to cover the uppermost one of the second semiconductor layers 20. The upper insulating layer TL may be formed of or include an insulating material, which has an etch selectivity with respect to the first and second semiconductor layers 10 and 20. For example, the upper insulating layer TL may be a silicon oxide layer.

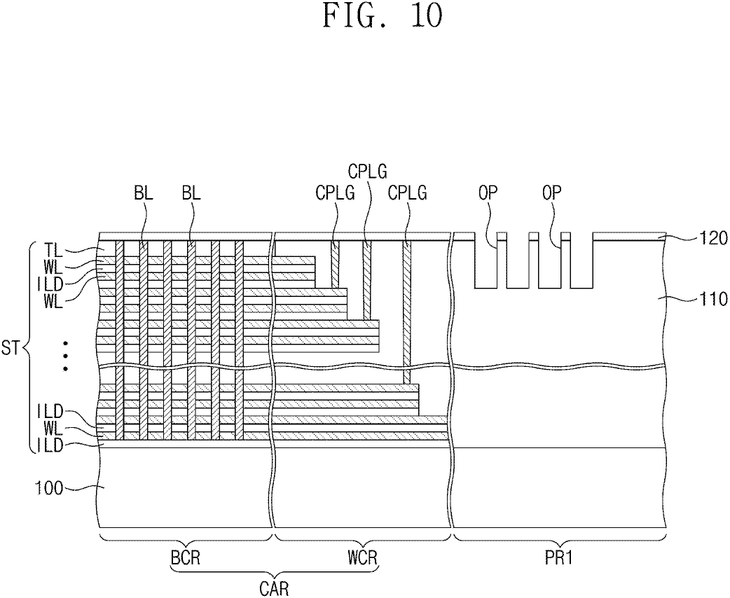

Referring to FIG. 10, the second semiconductor layers 20 of the mold structure MS may be replaced with the interlayer insulating patterns ILD, and the semiconductor patterns SP described with reference to FIGS. 6 and 8 may be formed from the first semiconductor layers 10.

Portions of the first semiconductor layers 10 may be left to form semiconductor patterns, and then, the word lines WL may be formed between the semiconductor patterns SP of FIGS. 6 and 7 and the interlayer insulating patterns ILD. In the bit line connection region BCR, the word lines WL may be formed to face and cross top and bottom surfaces of each semiconductor pattern SP. Each of the word lines WL may be disposed between vertically adjacent ones of the interlayer insulating patterns ILD.

A patterning process may be performed on the mold structure, before the formation of the word lines WL, and in an embodiment, as a result of the patterning process, the mold structure MS may have a staircase structure in the word line connection region WCR. Next, the planarization insulating layer 110 may be formed to cover the staircase structure of the mold structure MS, and thereafter, a replacement process may be performed such that the word lines WL form a staircase structure in the word line connection region WCR.

After the formation of the word lines WL, the bit lines BL may be formed to extend in a direction perpendicular to a top surface of the first semiconductor substrate 100. Each of the bit lines BL may be in contact with side surfaces of the semiconductor patterns SP, as previously described with reference to FIGS. 6 and 8.

After the formation of the bit lines BL, the cell contact plugs CPLG may be formed to penetrate the planarization insulating layer 110 and to be connected to the word lines WL.

The first interlayer insulating layer 120 may be formed on the planarization insulating layer 110 to cover top surfaces of the bit lines BL.

Thereafter, the openings OP may be formed by patterning the first interlayer insulating layer 120 and a portion of the planarization insulating layer 110 in the first peripheral region PR1. The openings OP may extend in a direction that is perpendicular to the top surface of the first semiconductor substrate 100. Here, bottom surfaces of the openings OP may be spaced apart from the top surface of the first semiconductor substrate 100. In other words, an etching depth of the openings OP may be smaller than a thickness of the planarization insulating layer 110. The openings OP may have various shapes (e.g., rectangular, circular, or elliptical shapes), when viewed in a plan view. In addition, the openings OP may be arranged in a zigzag or honeycomb shape.

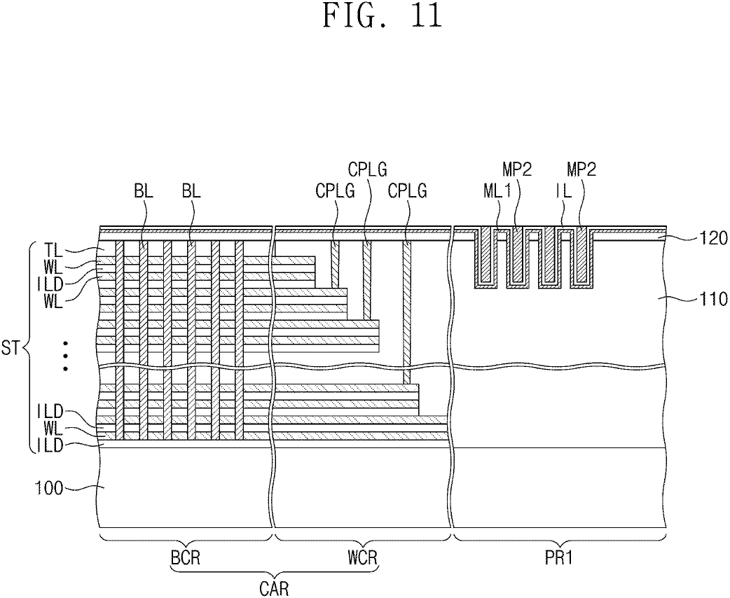

Referring to FIG. 11, a first metal layer ML1 may be deposited to cover inner surfaces of the openings and a top surface of the first interlayer insulating layer 120 with a uniform thickness. A dielectric layer IL of a uniform thickness may be deposited on the first metal layer ML1. A sum of thicknesses of the first metal layer ML1 and the dielectric layer IL may be less than a width of each opening OP. Accordingly, the first metal layer ML1 and the dielectric layer IL may not fill the openings completely.

The first metal layer ML1 may be formed of or include at least one of metallic materials (e.g., tungsten, titanium, and tantalum) and/or conductive metal nitrides (e.g., titanium nitride, tantalum nitride, and tungsten nitride).

The dielectric layer IL may be formed of at least one of metal oxides (e.g., HfO₂, ZrO₂, Al₂O₃, La₂O₃, Ta₂O₃, and TiO₂) or perovskite dielectric materials (e.g., SrTiO₃ (STO), (Ba,Sr)TiO₃ (BST), BaTiO₃, PZT, PLZT), and may have a single- or multi-layered structure.

After the formation of the dielectric layer IL, a second metal layer may be deposited to fill the openings, and a planarization process may be performed on the second metal layer. Accordingly, the second metal pattern MP2 may be formed in each opening. Here, second metal pattern MP2 may be formed of or include at least one of metallic materials (e.g., tungsten, titanium, and tantalum) or conductive metal nitride materials (e.g., titanium nitride, tantalum nitride, and tungsten nitride).

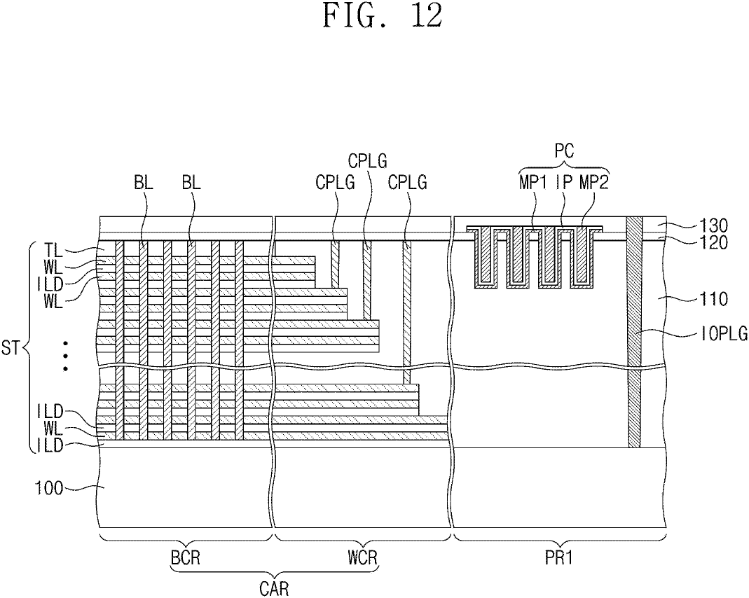

Next, a patterning process may be performed on the dielectric layer IL and the first metal layer ML1. That is, after the formation of the second metal patterns MP2, a mask pattern (not shown) may be formed on the second metal patterns MP2, and an anisotropic etching process using the mask pattern may be performed on the dielectric layer IL and the first metal layer ML1. Accordingly, as shown in FIG. 12, the dielectric material pattern IP and the first metal pattern MP1 may be formed. Meanwhile, in another embodiment, the planarization process on the second metal layer may be omitted, and in this case, after the deposition of the second metal layer, a patterning process may be performed on the second metal layer, the dielectric layer IL, and the first metal layer ML1. In this case, the second metal patterns may be connected to each other, thereby forming a single second metal pattern.

Thereafter, referring to FIG. 12, after the formation of the power capacitor PC, the second interlayer insulating layer 130 may be formed on the first interlayer insulating layer 120.

The input/output contact plug IOPLG may be formed in the first peripheral region PR1 to penetrate the first and second interlayer insulating layers 120 and 130 and the planarization insulating layer 110.

The formation of the input/output contact plug IOPLG may include forming a mask pattern (not shown) on the second interlayer insulating layer 130, forming a penetration hole exposing the first semiconductor substrate 100 by anisotropically etching the first and second interlayer insulating layers 120 and 130 and the planarization insulating layer 110 using the mask pattern as an etch mask, and filling the penetration hole with a conductive material.

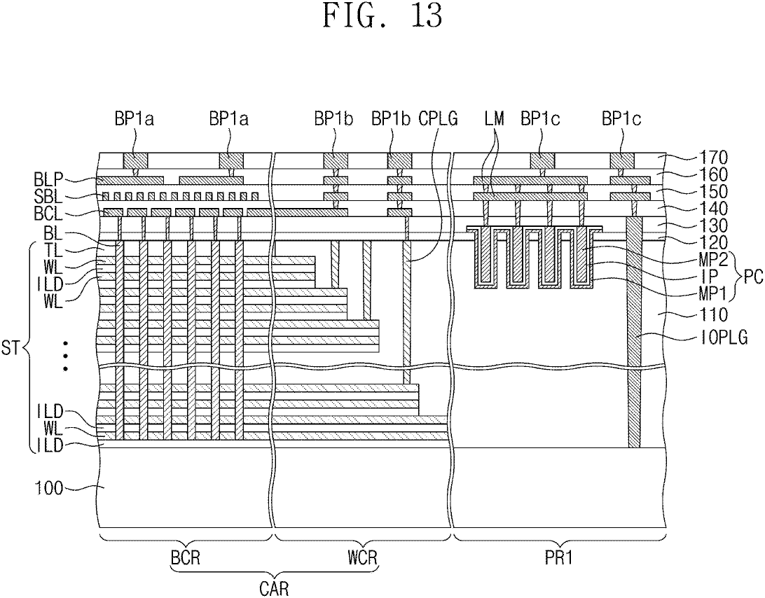

Referring to FIG. 13, after the formation of the input/output contact plug IOPLG, a plurality of interlayer insulating layers 140,150, 160, and 170 may be formed on the second interlayer insulating layer 130. In addition, connection lines BCL, sub-bit lines SBL, and landing pads BLP, which are electrically connected to the bit lines through contact plugs, may be sequentially formed in the bit line connection region BCR. During this process, conductive lines and contact plugs, which are electrically connected to the cell contact plugs CPLG, may be formed in the word line connection region WCR. Furthermore, conductive lines and contact plugs, which are electrically connected to the input/output contact plug IOPLG and the power capacitor PC, may be formed in the first peripheral region PR1.

The uppermost interlayer insulating layer (e.g., 170) may be formed, and then, the first bonding pads BP1a, BP1b, and BP1c may be formed in the uppermost interlayer insulating layer (e.g., 170). The first bonding pads BP1a, BP1b, and BP1c may be formed using a damascene process.

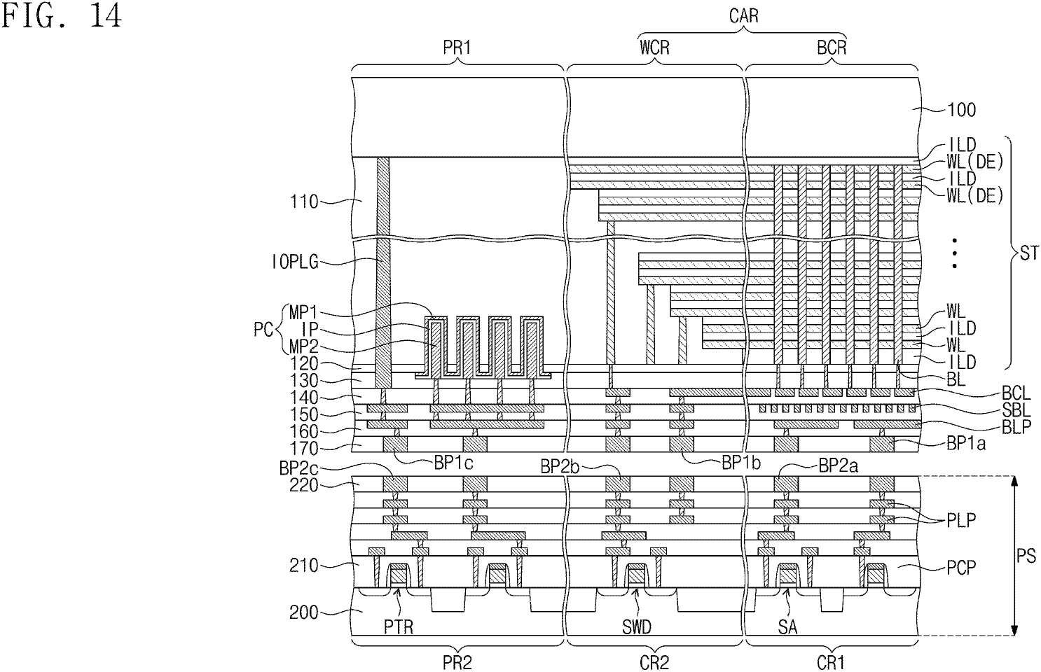

Referring to FIG. 14, the peripheral circuit structure PS may be prepared, and in an embodiment, the peripheral circuit structure PS may include the peripheral circuits SA, SWD, and PTR, which are formed on the second semiconductor substrate 200, and second bonding pads BP2, which are electrically connected to the peripheral circuits SA, SWD, and PTR. In an embodiment, the second semiconductor substrate 200 may include the first core region CR1, the second core region CR2, and the second peripheral region PR2. The sense amplifiers SA may be formed on the first core region CR1 of the second semiconductor substrate 200, and the sub-word line drivers SWD may be formed on the second core region CR2 of the second semiconductor substrate 200. In addition, the control circuits PTR may be formed on the second peripheral region PR2 of the second semiconductor substrate 200.

The first bonding pads BP1a, BP1b, and BP1c of the first semiconductor substrate 100 may be bonded to the second bonding pads BP2a, BP2b, and BP2c of the second semiconductor substrate 200.

The bonding process may be performed by performing a thermo-compression process, after placing the first bonding pads BP1a, BP1b, and BP1c to correspond to the second bonding pads BP2a, BP2b, and BP2c. As a result of the thermo-compression process, there may be no interface between the first bonding pads BP1a, BP1b, and BP1c and the second bonding pads BP2a, BP2b, and BP2c. Accordingly, the first bonding pads BP1a, BP1b, and BP1c may be bonded to the second bonding pads BP2a, BP2b, and BP2c, and the uppermost interlayer insulating layer 170 on the first semiconductor substrate 100 may be bonded to the uppermost peripheral interlayer insulating layer 220 on the second semiconductor substrate 200.

After the bonding between the first bonding pads BP1a, BP1b, and BP1c and the second bonding pads BP2a, BP2b, and BP2c, the first semiconductor substrate 100 may be removed. A grinding process, a planarization process, a wet etching process, and a dry etching process may be performed to remove the first semiconductor substrate 100.

As a result of the removal of the first semiconductor substrate 100, the input/output contact plug IOPLG and the planarization insulating layer 110 may be exposed to the outside, in the first peripheral region PR1. A portion (e.g., the lowermost interlayer insulating pattern ILD or the dummy word line DE) of the stack ST may be exposed to the outside, in the cell array region CAR.

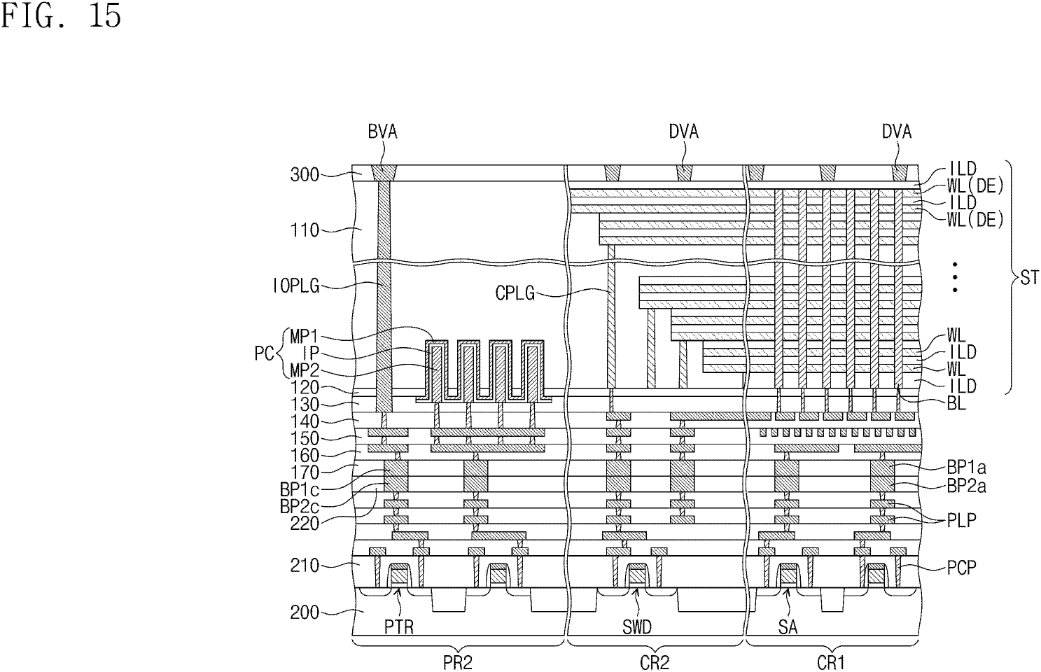

Next, referring to FIG. 15, the lower insulating layer 300 may be formed on the planarization insulating layer 110 and the stack ST.

Thereafter, the input/output vias BVA and the dummy vias DVA may be formed in the lower insulating layer 300. The input/output vias BVA and the dummy vias DVA may be formed by forming via holes penetrating the lower insulating layer 300 and filling the via holes with a conductive material. The input/output vias BVA and the dummy vias DVA may be formed of or include at least one of tungsten (W), titanium (Ti), tantalum (Ta), or nitride materials thereof.

The input/output vias BVA may be electrically connected to the input/output contact plug IOPLG. The dummy vias DVA may be surrounded by an insulating material and may be in an electrically-floated state.

Thereafter, referring back to FIG. 3, the input/output pad IOPAD and the dummy pads DPAD may be formed on the lower insulating layer 300. The input/output pad IOPAD and the dummy pads DPAD may be formed by depositing and patterning a metal layer on the lower insulating layer 300. The input/output pad IOPAD and the dummy pads DPAD may be formed of or include at least one of, for example, W, Al, Ti, Ta, Co, or Ru. As an example, the input/output pad IOPAD and the dummy pads DPAD may be formed of or include aluminum (Al).

After the formation of the input/output pad IOPAD and the dummy pads DPAD, a protection layer may be formed on the lower insulating layer 300, as shown in FIG. 3.

The protection layer 310 may cover the input/output pad IOPAD and the dummy pads DPAD and may be formed of or include a hydrogen-containing insulating material. The protection layer 310 may be formed by a deposition process using oxygen and silane gases, and in an embodiment, hydrogen may remain in the protection layer 310 when the deposition process is performed. As an example, the protection layer 310 may be a hydrogen-containing high-density-plasma (HDP) oxide layer. A hydrogen concentration in the protection layer 310 may be higher than a hydrogen concentration in the lower insulating layer 300.

The protection layer 310 may be formed using, for example, a plasma-enhanced chemical vapor deposition (PECVD) method, a high density plasma (HDP) method, and/or a sputtering deposition method.

After the formation of the protection layer 310, a high-temperature thermal treatment process (or a hydrogen treatment process) may be performed. During the thermal treatment process, the hydrogen may be supplied to transistors in the cell array structure through the dummy pads DPAD and the dummy vias DVA. The thermal treatment process may be performed at a temperature of about 300° C. to 500° C. Accordingly, it may be possible to prevent a leakage current, which is caused by silicon defects (e.g., dangling bonds) in the cell array structure. Thus, it may be possible to improve electric characteristics of the semiconductor memory device.

Next, the capping insulating layer 320 and the passivation layer 330 may be sequentially formed on the protection layer 310. The capping insulating layer 320 may include a silicon oxide layer, a silicon nitride layer, or a silicon oxynitride layer. The passivation layer 330 may be formed of or include at least one of polyimide-based materials (e.g., photo sensitive polyimide (PSPI)). The passivation layer 330 may be formed by a spin coating process.

Thereafter, the capping insulating layer 320 and the passivation layer 330 may be patterned to form the opening OP exposing a portion of the input/output pad IOPAD.

According to an embodiment of the inventive concept, bonding pads of a first substrate provided with memory cells may be bonded to bonding pads of a second substrate provided with peripheral circuits to connect a cell array structure to a peripheral circuit structure. Accordingly, an integration density of a semiconductor memory device may be increased. In addition, it may be possible to form a power capacitor in a portion of the cell array structure, without increasing a device area.

Furthermore, according to an embodiment of the inventive concept, input/output pads and dummy pads may be disposed near and extending toward the cell array structure and may be used as a pathway for supplying hydrogen to the cell array structure. Accordingly, when the semiconductor memory device is fabricated, electric characteristics of a memory cell array may be improved by a hydrogen treating process.

While example embodiments of the inventive concept have been particularly shown and described, it will be understood by one of ordinary skill in the art that variations in form and detail may be made therein without departing from the scope of the attached claims.

What is claimed is:

1. A semiconductor memory device, comprising:
a cell array structure comprising first bonding pads, which are electrically connected to memory cells; and
a peripheral circuit structure comprising second bonding pads, which are electrically connected to peripheral circuits and are bonded to the first bonding pads,
wherein the cell array structure comprises:
a stack comprising horizontal conductive patterns stacked in a vertical direction;
a vertical structure comprising vertical conductive patterns, which intersect the stack in the vertical direction; and
a power capacitor in a planarization insulating layer on a portion of the stack.

2. The semiconductor memory device of claim 1, wherein the power capacitor comprises:
a first metal pattern in an opening in the planarization insulating layer;
a second metal pattern on the first metal pattern; and
a dielectric material pattern between the first metal pattern and the second metal pattern.

3. The semiconductor memory device of claim 2, wherein, a height of the first metal pattern along the vertical direction is smaller than a thickness of the stack along the vertical direction.

4. The semiconductor memory device of claim 2, wherein the first metal pattern and the second metal pattern are electrically connected to a subset of the first bonding pads.

5. The semiconductor memory device of claim 1, wherein the cell array structure further comprises an input/output plug that penetrates the planarization insulating layer and is electrically connected to one of the first bonding pads.

6. The semiconductor memory device of claim 5, further comprising:
a lower insulating layer having a first surface and a second surface, which are opposite to each other; and
an input/output pad on the first surface of the lower insulating layer and is electrically connected to the input/output plug,
wherein the stack is on the second surface of the lower insulating layer.

7. The semiconductor memory device of claim 6, further comprising:
dummy pads, which are on the second surface of the lower insulating layer and include a same metallic material as the input/output pad; and
dummy vias electrically connected to the dummy pads,
wherein the dummy pads and dummy vias overlap with and extend toward the stack and the vertical structure in the vertical direction.

8. The semiconductor memory device of claim 1, wherein:
the cell array structure comprises a bit line connection region, a word line connection region, and a first peripheral region,
the stack has a staircase structure in the word line connection region,
the vertical conductive patterns intersect the horizontal conductive patterns , in the bit line connection region, and
the planarization insulating layer is in the word line connection region and the first peripheral region.

9. The semiconductor memory device of claim 1, wherein the cell array structure comprises a bit line connection region, a word line connection region, and a first peripheral region comprising the power capacitor,
and wherein the first bonding pads comprise:
first upper bonding pads in the bit line connection region and electrically connected to the vertical conductive patterns ;
second upper bonding pads in the word line connection region and electrically connected to the horizontal conductive patterns ; and
one or more third upper bonding pads in the first peripheral region and electrically connected to the power capacitor.

10. The semiconductor memory device of claim 9, wherein the peripheral circuit structure comprises a first core region that overlaps with the bit line connection region in the vertical direction, a second core region that overlaps with the word line connection region in the vertical direction, and a second peripheral region that overlaps with the first peripheral region in the vertical direction, and
wherein the second bonding pads comprise:
first lower bonding pads, which are in the first core region, are electrically connected to sense amplifiers, and are bonded to the first upper bonding pads;
second lower bonding pads, which are in the second core region, are electrically connected to sub-word line drivers, and are bonded to the second upper bonding pads; and
one or more third lower bonding pads, which are in the second peripheral region, are electrically connected to control circuits, and are bonded to the one or more third upper bonding pads.

11. The semiconductor memory device of claim 1, wherein:
the horizontal conductive patterns of the stack comprise word lines, which are parallel to a first surface of a lower insulating layer, and
the vertical conductive patterns of the vertical structure comprise bit lines, which are perpendicular to the first surface of the lower insulating layer.

12. The semiconductor memory device of claim 11, wherein:
the cell array structure comprises semiconductor patterns, which are three-dimensionally disposed, and
respective ones of the word lines face or intersect top and bottom surfaces of respective ones of the semiconductor patterns.

13. The semiconductor memory device of claim 12, wherein the cell array structure further comprises data storage elements on first side surfaces of the semiconductor patterns.

14. The semiconductor memory device of claim 13, wherein the data storage elements comprise:
storage node electrodes, which are in contact with the first side surfaces of the semiconductor patterns, respectively;
a plate electrode on the storage node electrodes; and
a capacitor dielectric layer between the plate electrode and the storage node electrodes.

15. A semiconductor memory device, comprising:
a cell array structure comprising first bonding pads electrically connected to memory cells; and
a peripheral circuit structure comprising second bonding pads electrically connected to peripheral circuits and bonded to the first bonding pads,
wherein the cell array structure comprises:
a lower insulating layer having a first surface and a second surface, which are opposite to each other;
a stack comprising horizontal conductive patterns , which are stacked on the first surface of the lower insulating layer;
a vertical structure comprising vertical conductive patterns penetrating the stack;
a power capacitor in a planarization insulating layer on the stack;
an input/output plug penetrating the planarization insulating layer; and
an input/output pad on the second surface of the lower insulating layer and electrically connected to the input/output plug,
wherein the power capacitor is between the first bonding pads and the input/output pads, when viewed in a vertical section.

16. The semiconductor memory device of claim 15, wherein the power capacitor comprises:
a first metal pattern, which is conformally extends along a plurality of openings in the planarization insulating layer;
second metal patterns, which are respectively provided in the openings having the first metal pattern therein; and
a dielectric material pattern between the first metal pattern and the second metal patterns.

17. The semiconductor memory device of claim 15, further comprising:
dummy pads, which are on the second surface of the lower insulating layer and include a same metallic material as the input/output pad; and
dummy vias electrically connected to the dummy pads,
wherein the dummy pads and dummy vias overlap with and extend toward the stack and the vertical structure in a vertical direction.

18. The semiconductor memory device of claim 15, wherein:
the cell array structure comprises semiconductor patterns, which are three-dimensionally disposed on the first surface of the lower insulating layer, and data storage elements, which are on first side surfaces of the semiconductor patterns, and
respective ones of the horizontal conductive patterns face or intersect top and bottom surfaces of respective ones of the semiconductor patterns.

19. A semiconductor memory device, comprising:
a cell array structure comprising first bonding pads electrically connected to memory cells in a cell array region, and a first peripheral region that is adjacent the cell array region; and
a peripheral circuit structure comprising second bonding pads electrically connected to peripheral circuits and bonded to the first bonding pads, the peripheral circuit structure comprising a first core region that overlaps with a bit line connection region in a vertical direction, a second core region that overlaps with a word line connection region in the vertical direction, and a second peripheral region that overlaps with the first peripheral region in the vertical direction,
wherein the cell array structure comprises:
a lower insulating layer having a first surface and a second surface, which are opposite to each other;
a stack comprising word lines that are in the cell array region and are stacked on the first surface of the lower insulating layer in the vertical direction;
a vertical structure comprising bit lines that are in the cell array region and penetrate the stack;
a planarization insulating layer in the cell array region and the first peripheral region and on the stack;
a power capacitor in the first peripheral region and in the planarization insulating layer, the power capacitor comprising a first metal pattern in an opening in the planarization insulating layer, a second metal pattern on the first metal pattern, and a dielectric material pattern between the first metal pattern and the second metal pattern;
an input/output plug in the first peripheral region and penetrating the planarization insulating layer; and
an input/output pad in the first peripheral region and on the second surface of the lower insulating layer and electrically connected to the input/output plug.

20. The semiconductor memory device of claim 19, wherein the first bonding pads comprise:
first upper bonding pads, which are in the bit line connection region and are electrically connected to the bit lines;
second upper bonding pads, which are in the word line connection region and are electrically connected to the word lines;
one or more third upper bonding pads, which are in the first peripheral region and are electrically connected to the power capacitor, and
wherein the second bonding pads comprise:
first lower bonding pads, which are in the first core region, are electrically connected to sense amplifiers, and are bonded to the first upper bonding pads;
second lower bonding pads, which are in the second core region, are electrically connected to sub-word line drivers, and are bonded to the second upper bonding pads; and
one or more third lower bonding pads, which are in the second peripheral region, are electrically connected to control circuits, and are bonded to the third upper bonding pads.
